(19) United States
(12) Patent Application Publication
(10) Pub. No.: US 2016/0039668 A1
(43) Pub. Date: Feb. 11, 2016

(54) APPARATUS AND METHOD TO FABRICATE MEMS DEVCE

(71) Applicant: INVENSENSE, INC., San Jose, CA (US)

(72) Inventor: CERINA ZHANG, SUNNYVALE, CA (US)

(21) Appl. No.: 14/454,722

(22) Filed: Aug. 8, 2014

(51) Int. Cl. B81C 1/00; B81B 7/00

(52) U.S. Cl. CPC B81C 1/00357; B81B 7/0032; B81C 1/00539; B81C 1/00531

(57) ABSTRACT

A MEMS device and fabrication of MEMS device is disclosed. The method includes providing a device layer, disposing a sacrificial layer over a first surface of the device layer, forming at least one MEMS feature in the device layer, wherein the formed MEMS feature is attached to the sacrificial layer. Selective portions of the sacrificial layer are removed so as to permit movement of the formed MEMS feature.

### RELATED APPLICATION

None

### TECHNICAL FIELD

The present invention relates generally to microelectromechanical systems (MEMS) device and more particularly, to MEMS device and fabrication of MEMS device.

### DESCRIPTION OF RELATED ART

MEMS devices are formed using various semiconductor manufacturing processes. MEMS devices may have one or more MEMS features. MEMS features may be fixed or movable portions. In some examples, MEMS sensors have one or more sense material, which react to an external influence imparting a force onto the movable portions. The sense material can be the MEMS structural layer or a deposited layer. The MEMS sensor may be configured to measure these movements induced by the external influence to determine the type and extent of the external influence.

MEMS features are formed using one or more semiconductor processes, by forming trenches (for example, by selectively removing material from a substrate). Sometimes, some of the semiconductor processes may create MEMS features with undulations or scallops along a sidewall of the MEMS feature. Sometimes, MEMS feature may have uneven sidewalls or tapered sides, due to the nature of etching method such as deep reactive ion etching (“DRIE”_or unwanted movement of the MEMS feature during the fabrication process. It may be desirable to minimize uneven sidewalls or tapered sides of MEMS features formed as part of a MEMS device.

With one or more of these needs in mind, the current disclosure arises. This brief summary has been provided so that the nature of the disclosure may be understood quickly. A more complete understanding of the disclosure can be obtained by reference to the following detailed description of the various embodiments thereof in connection with the attached drawings.

### SUMMARY OF THE INVENTION

In one embodiment, a method to fabricate a MEMS device is disclosed. The method includes providing a device layer. A sacrificial layer is disposed over a first surface of the device layer. At least one MEMS feature is formed on the device layer, wherein the formed MEMS feature is attached to the sacrificial layer. Selective portions of the sacrificial layer is removed so as to permit movement of the formed MEMS device.

In yet another embodiment, a MEMS device is disclosed. The MEMS device includes a device layer. A sacrificial layer is disposed over a first surface of the device layer. At least one MEMS feature is formed on the device layer, wherein the formed MEMS feature is attached to the sacrificial layer. Selective portions of the sacrificial layer are removed so as to permit movement of the formed MEMS feature.

This brief summary is provided so that the nature of the disclosure may be understood quickly. A more complete understanding of the disclosure can be obtained by reference to the following detailed description of the preferred embodiments thereof in connection with the attached drawings.

### BRIEF DESCRIPTION OF THE DRAWINGS

The foregoing and other features of several embodiments are described with reference to the drawings. In the drawings, the same components have the same reference numerals. The illustrated embodiments are intended to illustrate but not limit the invention. The drawings include the following Figures:

FIG. 1 shows a MEMS device, according to one aspect of the present disclosure;

FIG. 2A-2F show a series of cross-section of MEMS device during fabrication of the MEMS device of FIG. 1, according to an aspect of the present disclosure; and

FIG. 3 shows a flow diagram describing the fabrication of the MEMS device, according to one aspect of the present disclosure.

### DETAILED DESCRIPTION

To facilitate an understanding of the adaptive aspects of the present disclosure, exemplary MEMS device and method to fabricate MEMS device is described. The specific construction and operation of the adaptive aspects of the MEMS device and method to fabricate MEMS device of the present disclosure are described in detail with reference to the drawings.

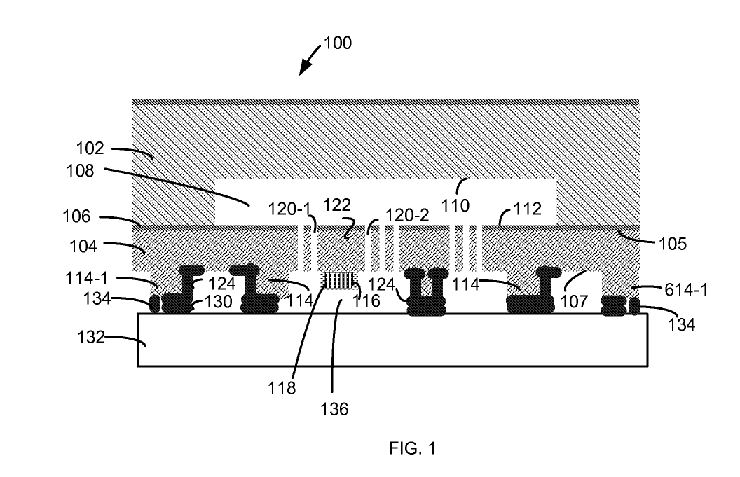

Now, referring to FIG. 1, an example MEMS device 100 is described. MEMS device 100 includes a handle layer 102 and a device layer 104. One or more sensors are formed on the device layer 104. An example magnetic sensor will be described with reference to the MEMS device 100. Magnetic sensor may be configured as a compass. As one skilled in the art appreciates, additional or other sensors may be formed on the device layer, for example, an accelerometer, a gyroscope, a pressure sensor, a microphone and a speaker.

A sacrificial layer 106 is disposed over a first surface 105 of the device layer 104. In one example, the sacrificial layer 106 bonds the handle layer 102 to device layer 104, to form an upper cavity 108, defined by the lower side 110 of the handle layer 102 and upper side 112 of the sacrificial layer 106. Other functions and features of the sacrificial layer 106 will be later described in detail. Now referring to device layer 104, a plurality of standoff 114 structures are formed on the device layer 104, for example, by deep reactive ion etching (DRIE) process. Magnetic films are deposited, patterned and magnetized on the second surface 107 of the device layer 104, to form a first permanent magnet 116. The first permanent magnet 116 is oriented in a predefined direction by applying an external magnetic field. In some embodiments, a protective layer 118 is deposited over the first permanent magnet 116, to prevent oxidization of the first permanent magnet 116.

FIG. 1 also shows trench patterns 120-1 and 120-2, a MEMS feature 122 and device pads 124. In one example, a movable MEMS feature 122 is created by forming a plurality of trench patterns 120-1 and 120-2 on the device layer 104, for example, from the second surface 107 to the first surface 105 of the device layer 104. Formation of the trench patterns and configuration of the MEMS feature to be movable will be later described in detail. First permanent magnet 116 is located on the MEMS feature 122. Next, device pads 124, preferably made of a conductive material, for example, germanium alloys are deposited and patterned on the device layer 104.

In one example, device pads 124 may be configured to be coupled to one or more conductors 130 disposed over base substrate 132 to provide a communication path to various sensors formed on the device layer 104. Base substrate 132 may include one or more integrated circuits (not shown) to process various signals generated by various sensors. Standoff 114-1 surrounds various devices formed on the device layer 104. Height of the standoff 114-1, along with a seal ring 134 define height of a lower cavity 136.

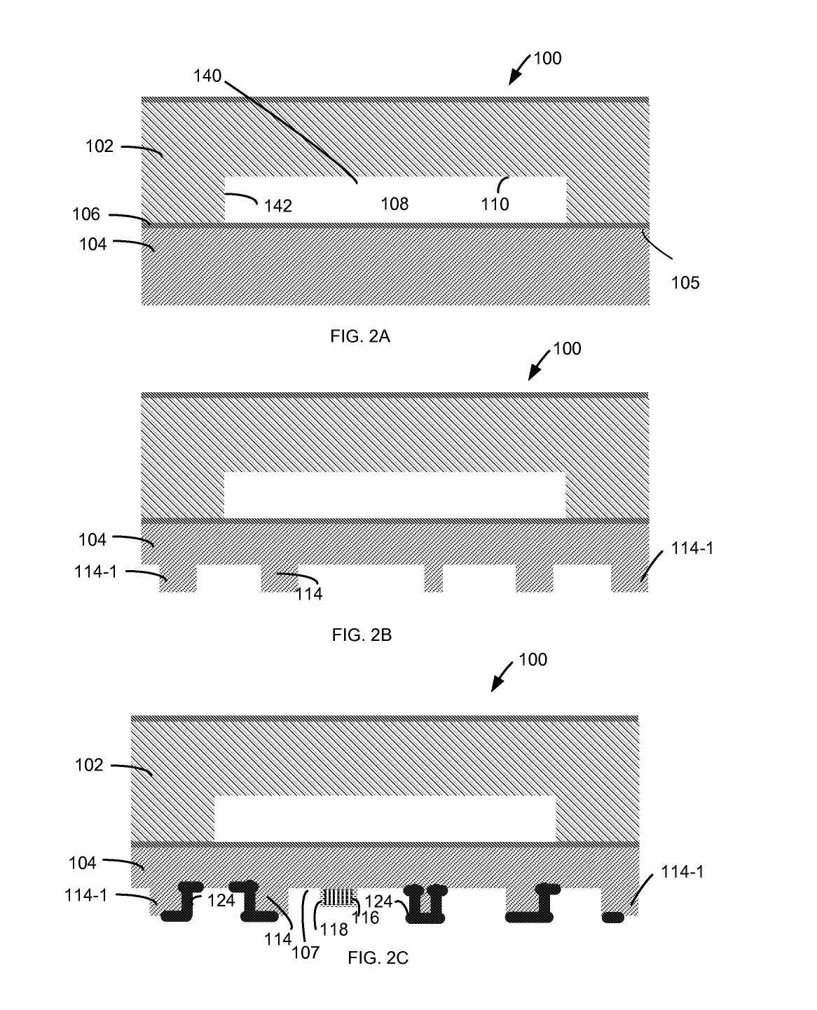

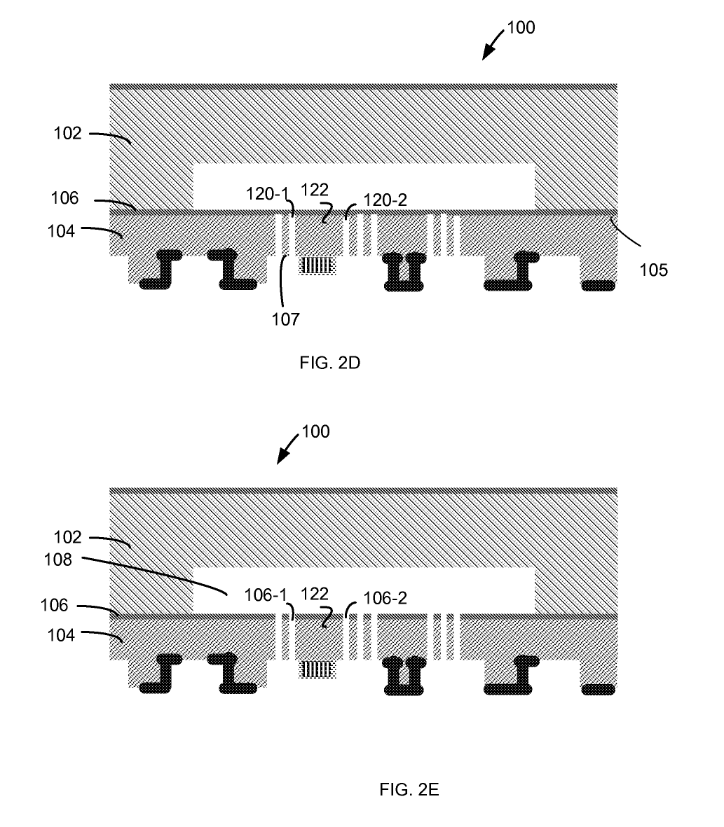

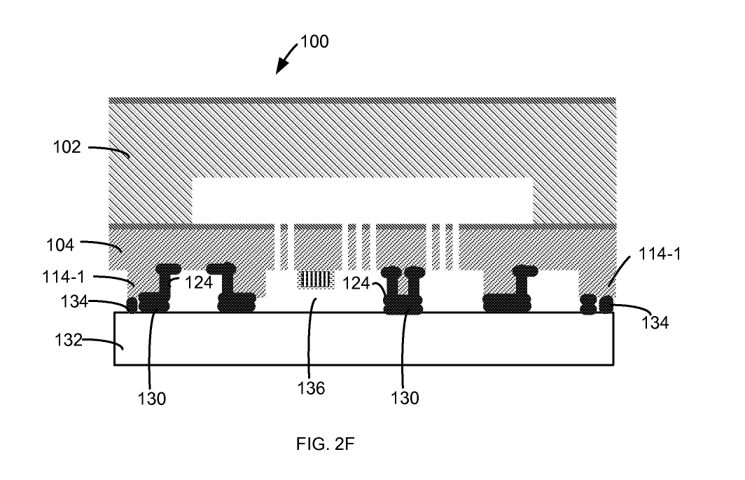

Now, referring to FIGS. 2A-2F, using a series of cross-section drawings of the MEMS device, various fabrication stages involved in the fabrication of the MEMS device according to an example of this disclosure will be described.

Now, referring to FIG. 2A, MEMS device 100 with handle layer 102 and device layer 104 is shown. Handle layer 102 includes a well portion 140 defined by lower side 110 and side wall 142, which define a portion of the upper cavity 108. Handle layer 102 may be a silicon wafer. A sacrificial layer 106 is disposed over a first surface 105 of the device layer 104. Device layer 104 may be a silicon substrate. Sacrificial layer 106 may be a dielectric material deposited over the first surface 105 of the device layer 104. The sacrificial layer 106 may be an oxide, for example, silicon oxide. In some examples, a thin layer of the sacrificial layer 106 may also be deposited over portions of the handle layer 102. For example, a thin layer of the sacrificial layer may be deposited over portions of the handle layer 102 that may come in contact with the device layer 104.

The handle layer 102 and device layer 104 are then bonded together, for example, by fusion bonding. The sacrificial layer 106 may facilitate the fusion bonding of the handle layer 102 to the device layer 104. Upon fusion bonding, upper cavity 108 is formed.

The thickness of the sacrificial layer 106 is so chosen that available oxide material is sufficient to form a strong fusion bonding between the handle layer 102 and device layer 104. Further, the sacrificial layer 106 provides a stable base to the device layer, as various parts and features are formed on the device layer 104, which will be further explained in detail. The thickness of the sacrificial layer 106 may be of the order of about 0.5 um to about 2 um and may be more preferably of the order of about 1 um.

Now, referring to FIG. 2B, MEMS device 100 is further shown with a plurality of standoff 114 structures formed on the device layer 104. In some examples, the plurality of standoff 114 structures are formed by deep reactive ion etching (DRIE) process.

Now, referring to FIG. 2C, MEMS device 100 is further shown with a first permanent magnet 116 formed over the second surface 107 of the device layer 104. For example, magnetic films are deposited, patterned and magnetized on the second surface 107 of the device layer 104, to form a first permanent magnet 116. The first permanent magnet is oriented in a predefined direction by applying an external magnetic field. In some examples, a protective layer 118 is deposited over the first permanent magnet 116, to prevent oxidization of the first permanent magnet 116. Device pads 124, preferably, made of a conductive material is deposited and patterned on the device layer 104. For example, the device pads 124 may be formed on one or more standoff 114. In some examples, an alloy of germanium may be deposited to form device pads. In some examples, an alloy of gold may be deposited to form device pads.

Now referring to FIG. 2D, MEMS device 100 is further shown with trench patterns 120-1 and 120-2 and MEMS feature 122. The trench patters 120-1 and 120-2 are formed by selectively etching the device layer 104, from the second surface 107 to the first surface 105. In some examples, the selective etching of the device layer 104 may be a dry etch process, for example, a plasma etching. The dry etch process may be a DRIE process. In some examples, the selective etching of the device layer 104 may be a wet etch process, for example, a chemical etch process. The wet etch process may use nitric acid (HNO3), plushydroflouric acid (HF), potassium hydroxide (KOH), ethlylenediamine pyrocatechol (EDP), or Tetramethylammonium hydroxide (TMAH) as the reactive agent.

As one skilled in the art appreciates, depending upon the depth of the trench patterns to be formed, etching process may be performed in stages. When etching process is performed in stages, side walls of the trench pattern may undulate, for example, with an amplitude of about 100 nm to about 500 nm. Sometimes, these undulations may be referred to as scallops. As the trench patterns only extend from the second surface 107 to the first surface 105 of the device layer 104, the MEMS feature 122 is still held by the sacrificial layer 106. In some examples, the scallops may be removed using focused ion beam milling. By ion milling the sidewalls of the MEMS features, a substantially straight sidewall may be created. Some of the benefits of a substantially straight sidewalls of the MEMS feature includes reducing the system error in a micro-electro-mechanical system introduced by proof mass, electrostatic force or mechanical spring mismatch. Examples of errors are quadrature error in a gyroscope, and cross-axis coupling in an accelerometer.

Now, referring to FIG. 2E, the MEMS device 100 is shown with selective portions, for example, selective portions 106-1 and 106-2 of the sacrificial layer 106 removed so as to extend the trench pattern all the way to the upper cavity 108. By extending the trench pattern all the way to the upper cavity 108, the MEMS feature 122 is released from its attachment to the sacrificial layer 106 and is movable relative to the device layer 104. The selective portion 106-1 and 106-2 of the sacrificial layer 106 may be removed or etched for example, using a dry etch process or a wet etch process. In some examples, selective portion 106-1 and 106-2 of the sacrificial layer 106 is removed by using a buffered oxide etch (BOE) process. In some examples, the selective portion 106-1 and 106-2 of the sacrificial layer 106 is removed by using a vapor hydrofluoric acid (VHF) process.

As one skilled in the art appreciates, after the formation of the trench patterns 120-1 and 120-2, in some examples, substantially all of the sacrificial layer 106 disposed inside the upper cavity 108 may be removed. For example, after the formation of all the trench patterns on the device layer 104, substantially all of the sacrificial layer 106 disposed inside the upper cavity 108 may be removed, yet retaining the portion of the sacrificial layer 106 that bonds the device layer 104 and the handle layer 102.

Now, referring to FIG. 2F, the MEMS device 100 is shown with the base substrate 132 with a plurality of conductors 130 disposed over base substrate 132 to provide a communication path to various sensors formed on the device layer 104. Plurality of conductors 130 are configured to electrically couple to the device pads 124. In some examples, the device pads 124 may be an alloy of gold and the plurality of conductors 130 are also alloy of gold. In this example, the device pads 124 and conductors 130 are eutectic bonded to provide a conductive path between the device pads 124 and conductors 130. In some examples, the device pads 124 may be an alloy of germanium and the plurality of conductors 130 may be an alloy of aluminum. In this example, the device pads 124 and conductors 130 are anodic bonded to provide a conductive path between the device pads 124 and conductors 130.

Base substrate 132 may include one or more integrated circuits (not shown) to process various signals generated by various sensors formed on the device layer 104. Standoff 114-1 surrounds various devices formed on the device layer 104. Height of the standoff 114-1, along with a seal ring 134 define height of the lower cavity 136. In some examples, the seal ring 134 hermitically seals the lower cavity 136.

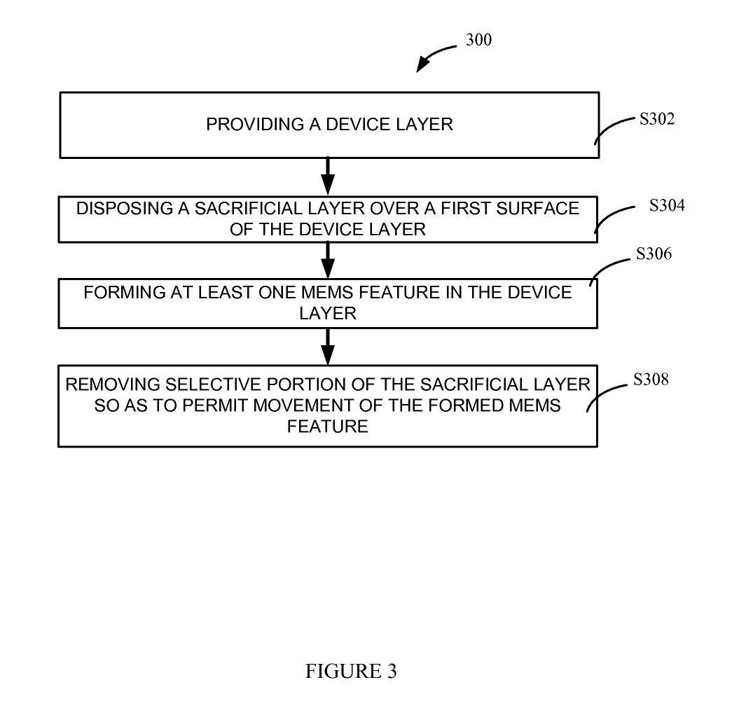

Now, referring to FIG. 3, an example flow diagram 300 will be described. In block S302, a device layer is provided. For example, a device layer 104 is provided.

In block S304, a sacrificial layer is disposed over a first surface of the device layer. For example, sacrificial layer 106 is disposed over the first surface 105 of the device layer 104.

In block S306, at least one MEMS feature is formed on the device layer. For example, MEMS feature 122 is formed on the device layer 104. In some examples, standoff 114, other elements of a sensor, for example, a permanent magnet 116, a plurality of device pads 124 and trenches 120-1 and 120-2 may be formed over the device layer 104.

In block S308, selective portions of the sacrificial layer is removed so as to permit movement of the formed MEMS feature. For example, selective portions 106-1 and 106-2 of the sacrificial layer 106 is removed so as to permit movement of the formed MEMS feature 122 on the device layer 104. In some examples, a base substrate 132 with a plurality of conductors 130 disposed over the base substrate 132 is electrically coupled to the device pads 124 disposed over the device layer 104 to provide a conductive path to one or more integrated circuits disposed over the base substrate 132.

While embodiments of the present invention are described above with respect to what is currently considered its preferred embodiments, it is to be understood that the invention is not limited to that described above. To the contrary, the invention is intended to cover various modifications and equivalent arrangements within the spirit and scope of the appended claims.

What is claimed is:

1. A method to fabricate a MEMS device, comprising:
providing a device layer;
disposing a sacrificial layer over a first surface of the device layer;
forming at least one MEMS feature in the device layer, wherein the formed MEMS feature is attached to the sacrificial layer; and
removing selective portions of the sacrificial layer so as to permit movement of the formed MEMS feature.

2. The method of claim 1, further including:
providing a handle layer with a cavity; and
attaching the handle layer to the device layer, using a portion of the sacrificial layer.

3. The method of claim 2, further including:
forming a plurality of standoff on a second surface of the device layer, second surface opposite to the first surface;
depositing a metal film over the plurality of standoff;
providing a base substrate with a plurality of conductive pads; and
bonding the metal film deposited over the plurality of standoff with the plurality of conductive pads on the base substrate.

4. The method of claim 1, wherein the selective portions of the sacrificial layer is removed by a wet etch process.

5. The method of claim 1, wherein the selective portions of the sacrificial layer is removed by a dry etch process.

6. The method of claim 2, wherein forming the at least one MEMS feature further including subjecting the device layer to a plasma and selectively etching a portion of the device layer from a second surface, second surface opposite to the first surface, the sacrificial layer preventing the plasma to pass through a trench formed from the second surface of the device layer to the first surface of the device layer.

7. The method of claim 1, wherein the sacrificial layer is a dielectric material.

8. The method of claim 7, wherein the sacrificial layer is an oxide of silicon.

9. The method of claim 6, wherein the MEMS feature having a sidewall with a plurality of scallops, and ion milling the sidewall to remove the plurality of scallops.

10. The method of claim 3, wherein the bonding further including anodic bonding of the metal film disposed over the plurality of standoff with the plurality of conductive pads on the base substrate.

11. The method of claim 3, wherein the bonding further including eutectic bonding of the metal film disposed over the plurality of standoff with the plurality of conductive pads on the base substrate.

12. The method of claim 10, wherein the metal film is an alloy of aluminum and the plurality of conductive pads are alloy of germanium.

13. The method of claim 11, wherein the metal film and the plurality of conductive pads are alloys of gold.

14. A MEMS device, comprising:
a device layer;
a sacrificial layer disposed over a first surface of the device layer;
at least one MEMS feature formed in the device layer, wherein the formed MEMS feature is attached to the sacrificial layer; and
selective portions of the sacrificial layer is removed so as to permit movement of the formed MEMS feature.

15. The MEMS device of claim 14, further including:
a handle layer with a cavity; and
a portion of the sacrificial layer attaches the handle layer to the device layer.

16. The MEMS device of claim 15, further including:
a plurality of standoff formed on a second surface of the device layer, second surface opposite to the first surface, a metal film is deposited over the plurality of standoff;
a base substrate with a plurality of conductive pads; and
the metal film deposited over the plurality of standoff is bonded with the plurality of conductive pads on the base substrate.

17. The MEMS device of claim 14, wherein selective portions of the sacrificial layer is subjected to a chemical and removed.

18. The MEMS device of claim 14, wherein selective portions of the sacrificial layer is plasma etched and removed.

19. The MEMS device of claim 15, wherein the device layer is subjected to a plasma to selectively etch a portion of the device layer from a second surface, second surface opposite to the first surface, wherein the sacrificial layer prevents the plasma to pass through a trench formed from the second surface of the device layer to the first surface of the device layer.

20. The MEMS device of claim 14, wherein the sacrificial layer is a dielectric material.

21. The MEMS device of claim 20, wherein the sacrificial layer is an oxide of silicon.

22. The MEMS device of claim 19, wherein the MEMS feature having a sidewall with a plurality of scallops, and ion milling the sidewall to remove the plurality of scallops.

23. The MEMS device of claim 16, wherein the bonding further including anodic bonding of the metal film disposed over the plurality of standoff with the plurality of conductive pads on the base substrate.

24. The MEMS device of claim 16, wherein the bonding further including eutectic bonding of the metal film disposed over the plurality of standoff with the plurality of conductive pads on the base substrate.

25. The MEMS device of claim 15, wherein the metal film is an alloy of aluminum and the plurality of conductive pads are alloy of germanium.

26. The MEMS device of claim 15, wherein the metal film and the plurality of conductive pads are alloys of gold.
